(19) United States
(12) Patent Application Publication
(10) Pub. No.: US 2026/0020164 A1
(43) Pub. Date: Jan. 15, 2026

(54) ELECTRONIC DEVICE ASSEMBLY WITH A BIODEGRADABLE HOUSING STRUCTURE

(71) Applicant: DELL PRODUCTS L.P., Round Rock, TX (US)

(72) Inventors: Peng Lip GOH, Singapore (SG); Deeder AURONGZEB, Austin, TX (US)

(21) Appl. No.: 18/772,795

(22) Filed: Jul. 15, 2024

(51) Int. Cl. H05K 5/02; H01Q 1/22; H05K 1/03

(52) U.S. Cl. CPC H05K 5/02; H01Q 1/22; H05K 1/0366; H05K 5/0247; H05K 2201/10098

(57) ABSTRACT

Disclosed is an electronic device assembly, methods for producing the electronic device assembly, and methods of separating one or more component parts from the electronic device assembly for recycling. The electronic device assembly may include a biodegradable housing structure that includes a biodegradable chassis and a biodegradable cover. The biodegradable chassis may be adapted to house one or more component parts of an electronic device, where the biodegradable chassis includes an internal cavity with one or more integrated mechanical fastening member receivers. The biodegradable cover may be insertable into the internal cavity of the biodegradable chassis, and the biodegradable cover may include one or more mechanical fastening members insertable into the one or more integrated mechanical fastening member receivers to secure the one or more component parts between the biodegradable cover and the biodegradable chassis.

### BACKGROUND

### A. Field of the Disclosure

The disclosure generally relates to electronic device assemblies. More specifically, the disclosure relates to an electronic device assembly with a biodegradable housing structure.

### B. Description of Related Art

External devices, such as dongles, can be connected to a computer to provide or support additional functionalities, such as wireless communication, access to memory, support to software, or the like. Dongles may contain one or more electronic device component parts housed within a plastic cover and secured by glue. Newer models of these external devices with enhanced or better functionalities are introduced at an increasing pace, and many consumers replace these devices on a frequent basis. This creates certain environmental problems due to difficulties associated with recycling such devices, with such devices typically being disposed of in landfills instead.

### BRIEF SUMMARY

A discovery has been made that provides a solution to at least one or more of the aforementioned problems associated with difficulties associated with recycling some electronic devices. In one aspect, an electronic device assembly is provided that may include a biodegradable housing structure. The biodegradable housing structure may include a biodegradable chassis (adapted to house one or more component parts of an electronic device) and a biodegradable cover to secure the component parts. Thus, such an electronic device assembly according to the present disclosure may advantageously provide environmental benefits due to the biodegradable nature of its housing structure. Additionally, in some aspects, exposing the electronic device assembly to biodegradation may advantageously provide additional environmental benefits by allowing for selective removal of one or more of the component parts housed within the biodegradable chassis subsequent to biodegradation for recycling purposes.

Some aspects of the disclosure are directed to an electronic device assembly comprising a biodegradable housing structure. The biodegradable housing structure may include a biodegradable chassis and a biodegradable cover. The biodegradable chassis may be capable of or adapted to house one or more component parts of an electronic device (e.g., within an internal cavity of the chassis that includes one or more integrated mechanical fastening member receivers), and the biodegradable cover may be insertable into the internal cavity of the biodegradable chassis. The biodegradable cover may include one or more mechanical fastening members insertable into the one or more integrated mechanical fastening member receivers. By inserting the mechanical fastening members of the biodegradable cover into the integrated mechanical fastening member receivers within the internal cavity of the biodegradable chassis, the biodegradable cover may secure the component parts between the biodegradable cover and the biodegradable chassis.

In certain embodiments, the one or more component parts may include at least a printed circuit board and at least one antenna. In certain embodiments, the printed circuit board may include a biodegradable printed circuit board. The biodegradable printed circuit board can include a laminate formed from organic fibers impregnated with a water-soluble polymer and a halogen-free flame retardant.

In certain embodiments, the one or more component parts may further include one or more antenna supports disposed between the printed circuit board and the biodegradable cover. In certain embodiments, at least one of the one or more antenna supports may be formed from natural rubber. The at least one antenna can be housed over the printed circuit board via the one or more antenna supports. In certain embodiments, the at least one antenna includes at least one metal antenna. In certain embodiments, the at least one metal antenna includes a three-dimensional (3D) metal antenna for input/output radio waves and an audio antenna disposed between the 3D metal antenna and at least one of the antenna supports.

In certain embodiments, the biodegradable cover of the electronic device assembly may be disposed adjacent to one surface of the printed circuit board, and the electronic device assembly may further include a Universal Serial Bus (USB) connector electronically coupled to the printed circuit board and disposed adjacent to an opposite surface of the printed circuit board. In certain embodiments, the USB connector may include a USB Type-C (USB-C) connector. In certain embodiments, the electronic device assembly may be a small form factor wireless communication device having a USB Type-C (USB-C) connector.

In certain embodiments, the biodegradable chassis may be formed from a cellulose acetate based material, a polyhydroxyalkanoate (PHA), or both. In certain embodiments, the PHA is a poly (3-hydroxybutyrate) (PHB). In certain embodiments, the cellulose acetate based material (of the biodegradable chassis) may have one or more of the following material properties: i) a melt flow rate (MFR) of 14 g/10 min, as measured in accordance with ISO1133; ii) a specific gravity of 1.3, as measured in accordance with ISO1183; iii) an ultimate tensile strength of 46 MPa as measured in accordance with ISO527; iv) a flexural modulus of 57 MPa, as measured in accordance with ISO178; and a heat deformation temperature of 68° C., as measured in accordance with ISO75. In certain embodiments, the biodegradable cover may be formed from a cellulose acetate based material, a PHA), or both. In certain embodiments, the PHA is a PHB. In certain embodiments, the cellulose acetate based material (of the biodegradable cover) may have one or more of the following material properties: i) a MFR of 14 g/10 min, as measured in accordance with ISO1133; ii) a specific gravity of 1.3, as measured in accordance with ISO1183; iii) an ultimate tensile strength of 46 MPa, as measured in accordance with ISO527; iv) a flexural modulus of 2520 MPa, as measured in accordance with ISO178; v) a flexural strength of 57 MPa, as measured in accordance with ISO178; and a heat deformation temperature of 68° C., as measured in accordance with ISO75.

Some aspects of the disclosure are directed to a method for producing an electronic device assembly that may include housing one or more component parts of an electronic device within a biodegradable chassis and inserting a biodegradable cover into an internal cavity of the biodegradable chassis. The biodegradable cover can be inserted into the internal cavity of the biodegradable chassis by inserting one or more mechanical fastening members of the biodegradable cover into one or more integrated mechanical fastening member receivers of the biodegradable chassis. Inserting the one or more mechanical fastening members into the one or more integrated mechanical fastening member receivers may secure the one or more component parts between the biodegradable cover and the biodegradable chassis. In certain embodiments, the one or more component parts may include at least: a printed circuit board; at least one metal antenna; and one or more antenna supports disposed between the printed circuit board and the biodegradable cover (where at least one antenna support is formed from natural rubber). In certain embodiments, the at least one metal antenna may include a 3D metal antenna for input/output radio waves and an audio antenna disposed between the 3D metal antenna and at least one of the antenna supports. In certain embodiments, the biodegradable cover may be disposed adjacent to one surface of the printed circuit board, and the electronic device assembly may further include a USB connector (e.g., USB-C connector) that is electronically coupled to the printed circuit board and that is disposed adjacent to an opposite surface of the printed circuit board. In certain embodiments, the biodegradable chassis and/or the biodegradable cover may be formed from a cellulose acetate based material.

Some aspects of the disclosure are directed to a method for separating one or more component parts from an electronic device assembly for recycling. The method may include exposing the electronic device assembly to biodegradation and selectively removing one or more component parts of an electronic device (housed within a biodegradable chassis of the electronic device assembly) for recycling (e.g., subsequent to the biodegradation). In certain embodiments, the one or more component parts of the electronic device may be removed before, during and/or subsequent to the biodegradation. In certain embodiments, the one or more component parts of the electronic device are removed subsequent to the biodegradation. Biodegradation of the electronic device assembly can include biodegradation of the biodegradable chassis, a biodegradable cover, and/or a biodegradable printed circuit board. Biodegradation can be complete or partial biodegradation of the biodegradable chassis, biodegradable cover, and/or biodegradable printed circuit board.

Other embodiments of the invention are discussed throughout this application. Any embodiment discussed with respect to one aspect of the invention applies to other aspects of the invention as well and vice versa. Each embodiment described herein is understood to be embodiments of the invention that are applicable to other aspects of the invention. It is contemplated that any embodiment discussed herein can be implemented with respect to any method or composition of the invention, and vice versa. Furthermore, compositions the invention can be used to achieve methods of the invention.

The following includes definitions of various terms and phrases used throughout this specification.

The terms “about” or “approximately” are defined as being close to as understood by one of ordinary skill in the art. In one non-limiting embodiment, the terms are defined to be within 10%, preferably within 5%, more preferably within 1%, and most preferably within 0.5%.

The terms “wt. %,” “vol. %,” or “mol. %” refers to a weight percentage of a component, a volume percentage of a component, or molar percentage of a component, respectively, based on the total weight, the total volume of material, or total moles, that includes the component. In a non-limiting example, 10 grams of component in 100 grams of the material is 10 wt. % of component. The term “ppm” refer to parts per million by weight, based on the total weight, of material that includes the component.

The term “substantially” and its variations are defined to include ranges within 10%, within 5%, within 1%, or within 0.5%.

The terms “inhibiting” or “reducing” or “preventing” or “avoiding” or any variation of these terms, when used in the claims and/or the specification includes any measurable decrease or complete inhibition to achieve a desired result.

The term “effective,” as that term is used in the specification and/or claims, means adequate to accomplish a desired, expected, or intended result.

The use of the words “a” or “an” when used in conjunction with any of the terms “comprising,” “including,” “containing,” or “having” in the claims, or the specification, may mean “one,” but it is also consistent with the meaning of “one or more,” “at least one,” and “one or more than one.”

The phrase “and/or” means and or or. To illustrate, A, B, and/or C includes: A alone, B alone, C alone, a combination of A and B, a combination of A and C, a combination of B and C, or a combination of A, B, and C. In other words, “and/or” operates as an inclusive or.

The words “comprising” (and any form of comprising, such as “comprise” and “comprises”), “having” (and any form of having, such as “have” and “has”), “including” (and any form of including, such as “includes” and “include”) or “containing” (and any form of containing, such as “contains” and “contain”) are inclusive or open-ended and do not exclude additional, unrecited elements or method steps.

The electronic device assembly of the present invention can “comprise,” “consist(s) essentially of,” or “consist of” particular ingredients, components, compositions, etc. disclosed throughout the specification.

Other objects, features and advantages of the present invention will become apparent from the following detailed description and examples. It should be understood, however, that the detailed description and examples, while indicating specific embodiments of the invention, are given by way of illustration only and are not meant to be limiting. Additionally, it is contemplated that changes and modifications within the spirit and scope of the invention will become apparent to those skilled in the art from this detailed description. In further embodiments, features from specific embodiments may be combined with features from other embodiments. For example, features from one embodiment may be combined with features from any of the other embodiments. In further embodiments, additional features may be added to the specific embodiments described herein.

### BRIEF DESCRIPTION OF THE DRAWINGS

Advantages of the present invention may become apparent to those skilled in the art with the benefit of the following detailed description and upon reference to the accompanying drawings. While the invention is susceptible to various modifications and alternative forms, specific embodiments thereof are shown by way of example in the drawings. The drawings may not be to scale.

FIG. 1 depicts a schematic diagram of an electronic device assembly according to some embodiments of the disclosure.

FIG. 2 depicts an exploded view of a biodegradable housing structure according to some embodiments of the disclosure.

FIG. 3A depicts a schematic diagram of an electronic device according to some embodiments of the disclosure.

FIG. 3B depicts an exploded view of an electronic device according to some other embodiments of the disclosure, where the electronic device includes an audio antenna and a 3D antenna.

FIG. 4A depicts an exploded vertical side view of an electronic device assembly according to some embodiments of the disclosure.

FIG. 4B depicts an exploded horizontal side view of an electronic device assembly according to some embodiments of the disclosure.

FIG. 5 depicts a flow chart of a method for producing an electronic device assembly according to some embodiments of the disclosure.

FIG. 6 depicts a flow chart of a method of separating one or more component parts from an electronic device assembly for recycling according to some embodiments of the disclosure.

### DETAILED DESCRIPTION

The present disclosure describes an electronic device assembly containing an biodegradable housing structure or covering. The biodegradable housing structure can have a relatively high biodegradable content, for example greater than 50%. The biodegradable housing structure can form a relatively durable cover that is capable of housing one or more components of an electronic device. Use of the biodegradable housing structure with an electronic device assembly such as dongles can provide environment friendly sustainable devices that have a low carbon footprint.

These and other non-limiting aspects of the present disclosure are discussed in further detail in the following sections.

### A. Electronic Device Assembly

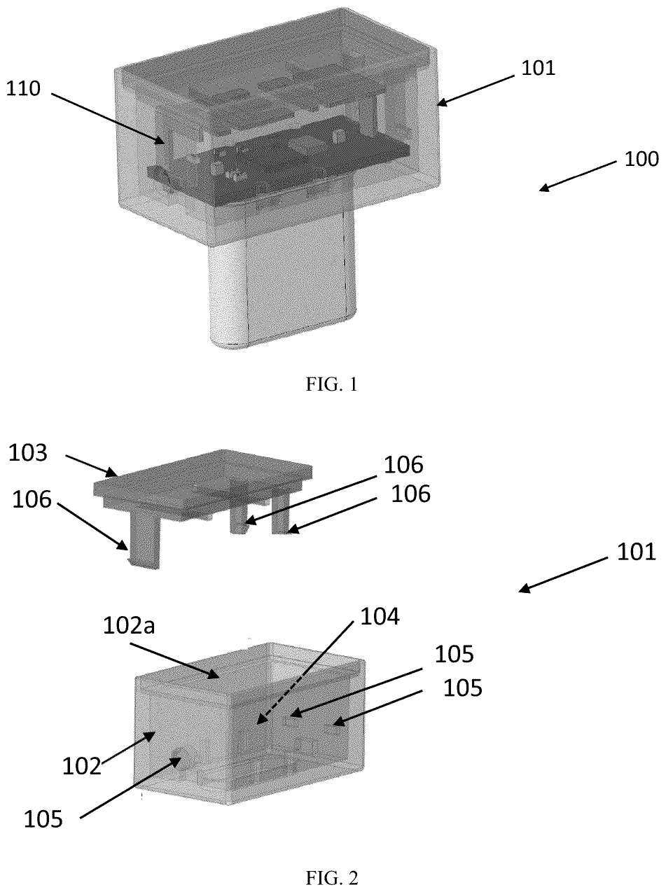

Referring to FIG. 1, a schematic diagram of an electronic device assembly 100 according to one example of the present disclosure is shown. FIG. 1 illustrates that the electronic device assembly 100 can include a biodegradable housing 101 and an electronic device 110. One or more components of the electronic device 110 can be housed within the biodegradable housing 101.

Referring to FIG. 2, an exploded view of the biodegradable housing 101 according to one example of the present disclosure is shown. FIG. 2 illustrates that the biodegradable housing 101 can include a biodegradable chassis 102 and a biodegradable cover 103. The biodegradable chassis 102 can include an internal cavity 104 with integrated mechanical fastening member receivers 105. The biodegradable chassis 102 can have an open side 102a, and the biodegradable cover 103 can be inserted into the internal cavity 104 through the open side 102a. FIG. 2 further illustrates that the biodegradable cover 103 can include mechanical fastening members 106 insertable into the integrated mechanical fastening member receivers 105 of the biodegradable chassis 102. By inserting the mechanical fastening members 106 into the integrated mechanical fastening member receivers 105, the biodegradable cover 103 can be inserted into the internal cavity 104. Referring back to FIG. 1, the mechanical fastening members 106 (as shown in FIG. 2) are depicted after being inserted into the integrated mechanical fastening member receivers 105 (as shown in FIG. 2), and the biodegradable cover 103 is depicted after being inserted into the internal cavity 104 (as shown in FIG. 2).

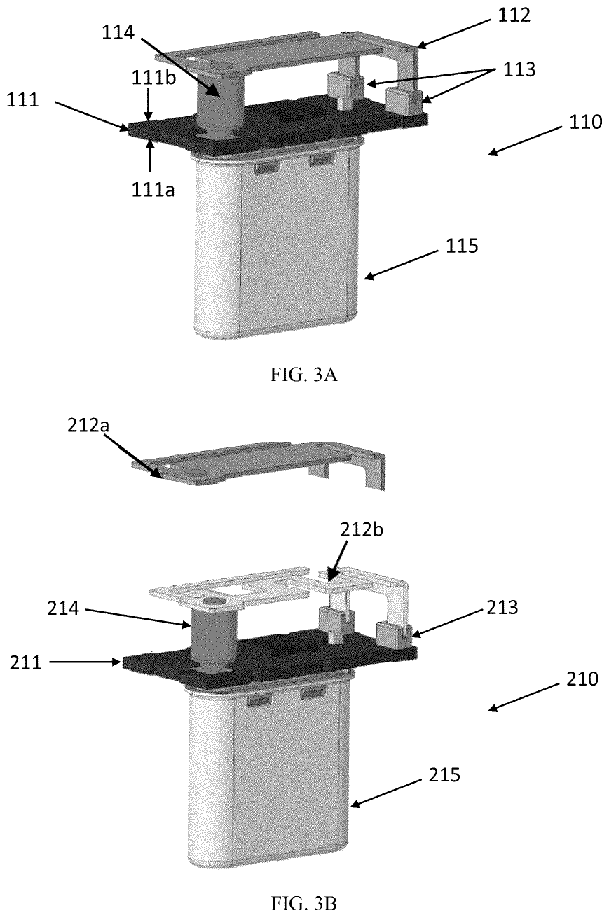

Referring to FIG. 3A, a schematic diagram of an electronic device 110 according to one example of the present disclosure is shown. The electronic device 110 can include a printed circuit board 111, an antenna 112, antenna supports 113, a pogo pin 114, and a USB connector 115. The antenna supports 113 can be housed over the printed circuit board 111. The pogo pin 114 can be electrically connected to the printed circuit board 111, and the antenna 112. The pogo pin 114 can be disposed between the printed circuit board 111, and the antenna 112. The antenna 112 can be housed over the printed circuit board 111 via the antenna supports 113. The USB connector 115 can be electronically coupled to the printed circuit board 111. The USB connector 115 can be connected to a surface 111a of the printed circuit board 111 that is opposite to the surface 111b of the printed circuit board 111 to which the antenna supports 113 and the pogo pin 114 are connected. The antenna 112 can be adjacent to the surface 111b. The antenna 112 can be a metal antenna. The antenna 112 can include a 3D metal antenna for input/output of radio waves, an audio antenna, or both. The 3D metal antenna and the audio antenna can be part of the same antenna or can form different antenna structure.

Referring to FIG. 3B, an exploded view of an electronic device 210 according to another example of the present disclosure is shown. The electronic device 210 can include a printed circuit board 211, antenna supports 213, a pogo pin 214, a USB connector 215, an 3D metal antenna 212a, and an audio antenna 212b. In the embodiment depicted in FIG. 3B, the antenna of the electronic device 210 includes both the 3D metal antenna 212a and the audio antenna 212b. FIG. 3B illustrates that, in some embodiments, the audio antenna 212b can be disposed between the 3D metal antenna 212a and the antenna supports 213.

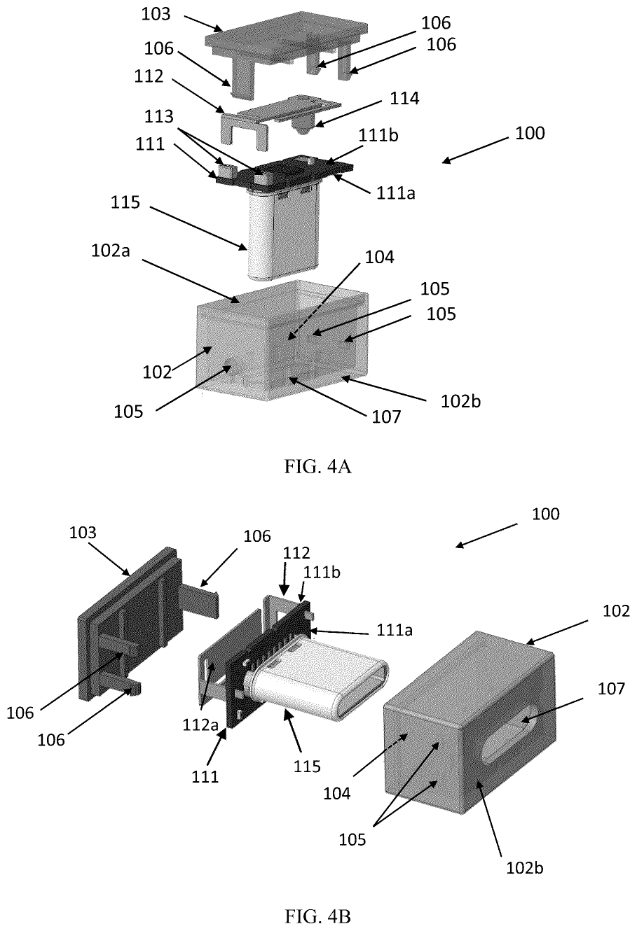

Referring to FIGS. 4A and 4B, an exploded vertical side view (FIG. 4A) and a horizontal side view (FIG. 4B) of the electronic device assembly 100 according to some examples of the present disclosure is shown. In each of the views depicted in FIGS. 4A and 4B, the biodegradable chassis 102, the biodegradable cover 103, the internal cavity 104, the integrated mechanical fastening member receivers 105, and the mechanical fastening members 106 of the biodegradable housing 101 are shown. Further, in each of the views depicted in FIGS. 4A and 4B, the printed circuit board 111, the antenna 112, the antenna supports 113, the pogo pin 114, and the USB connector 115 of the electronic device 110 are shown. FIGS. 4A and 4B further illustrate that, in some embodiments, the antenna 112 can be disposed between the printed circuit board 111 and the biodegradable cover 103. FIGS. 4A and 4B further illustrate that, in some embodiments, the antenna supports 113 and the pogo pin 114 can be disposed between the printed circuit board 111 and the biodegradable cover 103 and can be connected to a surface 111b of the printed circuit board 111 that is adjacent to the biodegradable cover 103. One or more component parts of the electronic device 110 (e.g., the printed circuit board 111, the antenna 112, the antenna supports 113, and pogo pin 114 can be housed inside the biodegradable housing 101 (see FIG. 1). FIG. 4A further illustrates that, in some embodiments, the USB connector 115 can be connected to a surface 111a of the printed circuit board 111 that is opposite to the surface 111b of the printed circuit board 111 that is adjacent to the biodegradable cover 103. In certain embodiments, the USB connector 115 can extend out of the internal cavity 104 and the biodegradable chassis 102 through a hole 107 in a wall 102b of the biodegradable chassis 102 (as depicted in the example of FIG. 1). In certain embodiments, the USB connector 115 can be oriented at a perpendicular direction with respect to the printed circuit board 111, such as the USB connector 115 extending out of the internal cavity 104 at a direction that is perpendicular to an orientation (for example, the plane of the surface 111a and 111b) of the printed circuit board 111. The wall 102b can be at a side that is opposite to the open side 102a of the biodegradable chassis 102.

The electronic device 100 can be an external device, such as a dongle, which when connected to a computer can provide or support additional functionalities, such as wireless communication, access to memory, support to a software, or the like.

In some embodiments, the printed circuit boards 111, 211 depicted in the previous figures can be a biodegradable printed circuit board. The biodegradable printed circuit board can include a laminate formed from i) organic fibers impregnated with a water-soluble polymer and ii) a halogen-free flame retardant.

In some embodiments, the antenna supports 113, 213 depicted in the previous figures can be formed from natural rubber. The natural rubber content of the antenna supports 113, 213 can be 20% to 100% (wt. %). In certain embodiments, the natural rubber content of the antenna supports 113, 213 may be 20% to 30%, 20% to 40%, 20% to 50%, 20% to 60%, 20% to 70%, 20% to 80%, 20% to 90%, 20% to 95%, 20% to 100%, 30% to 40%, 30% to 50%, 30% to 60%, 30% to 70%, 30% to 80%, 30% to 90%, 30% to 95%, 30% to 100%, 40% to 50%, 40% to 60%, 40% to 70%, 40% to 80%, 40% to 90%, 40% to 95%, 40% to 100%, 50% to 60%, 50% to 70%, 50% to 80%, 50% to 90%, 50% to 95%, 50% to 100%, 60% to 70%, 60% to 80%, 60% to 90%, 60% to 95%, 60% to 100%, 70% to 80%, 70% to 90%, 70% to 95%, 70% to 100%, 80% to 90%, 80% to 95%, 80% to 100%, 90% to 95%, 90% to 100%, or 95% to 100% (wt. %). In certain embodiments, the natural rubber content of the antenna supports 113, 213 may be 20%, 30%, 40%, 50%, 60%, 70%, 80%, 90%, 95%, or 100% (wt. %), or any value therein. In certain embodiments, the natural rubber content of the antenna supports 113, 213 may be at least 20%, 30%, 40%, 50%, 60%, 70%, 80%, 90%, or 95% (wt. %). In certain embodiments, the natural rubber content of the antenna supports 113, 213 may be at most 30%, 40%, 50%, 60%, 70%, 80%, 90%, 95% or 100% (wt. %).

In certain embodiments, the USB connector 115, 215 depicted in the previous figures can be any suitable USB connector, having any suitable plug types and USB standards. To illustrate, the USB connector 115, 215 depicted in the previous figures can be USB 1.0, 2.0, or 3.0 and USB Type-A, Type-B, Type-C, Mini-A, Mini-B, Micro-A or Micro-B. In certain embodiments, the USB connector 115, 215 may be a USB 2.0/1.0 Type-A, USB 2.0 Type-B, USB 3.0 Type-A, USB 2.0 Mini-A, USB 2.0 Mini-B, USB 3.0 Type-C, USB 2.0 Micro-A, USB 2.0 Micro-B, or USB 3.0 Micro-B. In certain embodiments, the USB connector 115, 215 depicted in the previous figures may be a Type-C USB connector. While not depicted in the previous figures, it will be appreciated that the electronic device assembly 100 (see FIG. 1) can be connected to a computer via the USB connector 115, 215 depicted in the previous figures.

In certain embodiments, the biodegradable chassis 102 depicted in the previous figures can be formed from a cellulose acetate based material, a PHA material (e.g., PHB), or both. For example, PHB can be degraded when it is exposed to a biologically active environment such as soil, sea water or fresh water, aerobic or anaerobic composting, activated sludge, sanitary landfill, or the like. The biologically active environment may contain microorganisms capable of degrading the PHB. Biodegrading the PHB by exposing it to a biologically active environment may have no or relatively low environmental effect. In certain embodiments, the cellulose acetate based material content of the biodegradable chassis 102 can be 50% to 100% (wt. %). In certain embodiments, the cellulose acetate based material content, the PHA (e.g., PHB) content (or both), of the biodegradable chassis 102 may be 50% to 100% (wt. %). In certain embodiments, the cellulose acetate based material content, the PHA (e.g., PHB) content (or both), of the biodegradable chassis 102 may be 50% to 60%, 50% to 70%, 50% to 80%, 50% to 90%, 50% to 95%, 50% to 98%, 50% to 100%, 60% to 70%, 60% to 80%, 60% to 90%, 60% to 95%, 60% to 98%, 60% to 100%, 70% to 80%, 70% to 90%, 70% to 95%, 70% to 98%, 70% to 100%, 80% to 90%, 80% to 95%, 80% to 98%, 80% to 100%, 90% to 95%, 90% to 98%, 90% to 100%, 95% to 98%, 95% to 100%, or 98% to 100% (wt. %). In certain embodiments, the cellulose acetate based material content, the PHA (e.g., PHB) content (or both), of the biodegradable chassis 102 may be 50%, 60%, 70%, 80%, 90%, 95%, 98%, or 100% (wt. %), or any value therebetween. In certain embodiments, the cellulose acetate based material content, the PHA (e.g., PHB) content (or both), of the biodegradable chassis 102 may be at least 50%, 60%, 70%, 80%, 90%, 95%, or 98% (wt. %). In certain embodiments, the cellulose acetate based material content, the PHA (e.g., PHB) content (or both), of the biodegradable chassis 102 may be at most 60%, 70%, 80%, 90%, 95%, 98%, or 100% (wt. %).

In certain embodiments, the biodegradable cover 103 depicted in the previous figures can be formed from a cellulose acetate based material, a PHA material (e.g., PHB), or both. The cellulose acetate based material content, the PHA (e.g., PHB) content (or both), of the biodegradable cover 103 may be 20% to 100% (wt. %). In certain embodiments, the cellulose acetate based material content, the PHA (e.g., PHB) content (or both), of the biodegradable cover 103 may be 50% to 100% (wt. %). In certain embodiments, the cellulose acetate based material content, the PHA (e.g., PHB) content (or both), of the biodegradable cover 103 may be 50% to 60%, 50% to 70%, 50% to 80%, 50% to 90%, 50% to 95%, 50% to 98%, 50% to 100%, 60% to 70%, 60% to 80%, 60% to 90%, 60% to 95%, 60% to 98%, 60% to 100%, 70% to 80%, 70% to 90%, 70% to 95%, 70% to 98%, 70% to 100%, 80% to 90%, 80% to 95%, 80% to 98%, 80% to 100%, 90% to 95%, 90% to 98%, 90% to 100%, 95% to 98%, 95% to 100%, or 98% to 100% (wt. %). In certain embodiments, the cellulose acetate based material content, the PHA (e.g., PHB) content (or both), of the biodegradable cover 103 may be 50%, 60%, 70%, 80%, 90%, 95%, 98%, or 100% (wt. %), or any range therebetween. In certain embodiments, the cellulose acetate based material content, the PHA (e.g., PHB) content (or both), of the biodegradable cover 103 may be at least 50%, 60%, 70%, 80%, 90%, 95%, or 98% (wt. %). In certain embodiments, the cellulose acetate based material content, the PHA (e.g., PHB) content (or both), of the biodegradable cover 103 may be at most 60%, 70%, 80%, 90%, 95%, 98%, or 100% (wt. %).

In certain embodiments, the cellulose acetate based material of the biodegradable chassis 102 and/or the biodegradable cover 103 depicted in the previous figures can have a MFR of 8 g/10 min to 20 g/10 min. In certain embodiments, the cellulose acetate based material of the biodegradable chassis 102 and/or the biodegradable cover 103 may have a MFR of 8 g/10 min to 10 g/10 min, 8 g/10 min to 12 g/10 min, 8 g/10 min to 13 g/10 min, 8 g/10 min to 14 g/10 min, 8 g/10 min to 15 g/10 min, 8 g/10 min to 16 g/10 min, 8 g/10 min to 18 g/10 min, 8 g/10 min to 20 g/10 min, 10 g/10 min to 12 g/10 min, 10 g/10 min to 13 g/10 min, 10 g/10 min to 14 g/10 min, 10 g/10 min to 15 g/10 min, 10 g/10 min to 16 g/10 min, 10 g/10 min to 18 g/10 min, 10 g/10 min to 20 g/10 min, 12 g/10 min to 13 g/10 min, 12 g/10 min to 14 g/10 min, 12 g/10 min to 15 g/10 min, 12 g/10 min to 16 g/10 min, 12 g/10 min to 18 g/10 min, 12 g/10 min to 20 g/10 min, 13 g/10 min to 14 g/10 min, 13 g/10 min to 15 g/10 min, 13 g/10 min to 16 g/10 min, 13 g/10 min to 18 g/10 min, 13 g/10 min to 20 g/10 min, 14 g/10 min to 15 g/10 min, 14 g/10 min to 16 g/10 min, 14 g/10 min to 18 g/10 min, 14 g/10 min to 20 g/10 min, 15 g/10 min to 16 g/10 min, 15 g/10 min to 18 g/10 min, 15 g/10 min to 20 g/10 min, 16 g/10 min to 18 g/10 min, 16 g/10 min to 20 g/10 min, or 18 g/10 min to 20 g/10 min. In certain embodiments, the cellulose acetate based material of the biodegradable chassis 102 and/or the biodegradable cover 103 may have a MFR of 8 g/10 min, 10 g/10 min, 12 g/10 min, 13 g/10 min, 14 g/10 min, 15 g/10 min, 16 g/10 min, 18 g/10 min, or 20 g/10 min, or any value therein. In certain embodiments, the cellulose acetate based material of the biodegradable chassis 102 and/or the biodegradable cover 103 has a MFR of at least 8 g/10 min, 10 g/10 min, 12 g/10 min, 13 g/10 min, 14 g/10 min, 15 g/10 min, 16 g/10 min, or 18 g/10 min. In certain embodiments, the cellulose acetate based material of the biodegradable chassis 102 and/or the biodegradable cover 103 has a MFR of at most 10 g/10 min, 12 g/10 min, 13 g/10 min, 14 g/10 min, 15 g/10 min, 16 g/10 min, 18 g/10 min, or 20 g/10 min. The MFR can be measured in accordance with ISO1133.

In certain embodiments, the he cellulose acetate based material of the biodegradable chassis 102 and/or the biodegradable cover 103 depicted in the previous figures can have a specific gravity of 0.8 to 1.8. In certain embodiments, the cellulose acetate based material of the biodegradable chassis 102 and/or the biodegradable cover 103 may have a specific gravity of 0.8 to 1, 0.8 to 1.1, 0.8 to 1.2, 0.8 to 1.3, 0.8 to 1.4, 0.8 to 1.5, 0.8 to 1.7, 0.8 to 1.8, 1 to 1.1, 1 to 1.2, 1 to 1.3, 1 to 1.4, 1 to 1.5, 1 to 1.7, 1 to 1.8, 1.1 to 1.2, 1.1 to 1.3, 1.1 to 1.4, 1.1 to 1.5, 1.1 to 1.7, 1.1 to 1.8, 1.2 to 1.3, 1.2 to 1.4, 1.2 to 1.5, 1.2 to 1.7, 1.2 to 1.8, 1.3 to 1.4, 1.3 to 1.5, 1.3 to 1.7, 1.3 to 1.8, 1.4 to 1.5, 1.4 to 1.7, 1.4 to 1.8, 1.5 to 1.7, 1.5 to 1.8, or 1.7 to 1.8. In certain embodiments, the cellulose acetate based material of the biodegradable chassis 102 and/or the biodegradable cover 103 may have a specific gravity of 0.8, 1, 1.1, 1.2, 1.3, 1.4, 1.5, 1.7, or 1.8, or any value therein. In certain embodiments, the cellulose acetate based material of the biodegradable chassis 102 and/or the biodegradable cover 103 may have a specific gravity of at least 0.8, 1, 1.1, 1.2, 1.3, 1.4, 1.5, or 1.7. In certain embodiments, the cellulose acetate based material of the biodegradable chassis 102 and/or the biodegradable cover 103 may have a specific gravity of at most 1, 1.1, 1.2, 1.3, 1.4, 1.5, 1.7, or 1.8. The specific gravity can be measured in accordance with ISO1183.

In certain embodiments, the cellulose acetate based material of the biodegradable chassis 102 and/or the biodegradable cover 103 depicted in the previous figures can have an ultimate tensile strength of 35 MPa to 55 MPa. In certain embodiments, the cellulose acetate based material of the biodegradable chassis 102 and/or the biodegradable cover 103 may have an ultimate tensile strength of 35 MPa to 40 MPa, 35 MPa to 42 MPa, 35 MPa to 44 MPa, 35 MPa to 46 MPa, 35 MPa to 48 MPa, 35 MPa to 50 MPa, 35 MPa to 55 MPa, 40 MPa to 42 MPa, 40 MPa to 44 MPa, 40 MPa to 46 MPa, 40 MPa to 48 MPa, 40 MPa to 50 MPa, 40 MPa to 55 MPa, 42 MPa to 44 MPa, 42 MPa to 46 MPa, 42 MPa to 48 MPa, 42 MPa to 50 MPa, 42 MPa to 55 MPa, 44 MPa to 46 MPa, 44 MPa to 48 MPa, 44 MPa to 50 MPa, 44 MPa to 55 MPa, 46 MPa to 48 MPa, 46 MPa to 50 MPa, 46 MPa to 55 MPa, 48 MPa to 50 MPa, 48 MPa to 55 MPa, or 50 MPa to 55 MPa. In certain embodiments, the cellulose acetate based material of the biodegradable chassis 102 and/or the biodegradable cover 103 may have an ultimate tensile strength of 35 MPa, 40 MPa, 42 MPa, 44 MPa, 46 MPa, 48 MPa, 50 MPa, or 55 MPa, or any value therein. In certain embodiments, the cellulose acetate based material of the biodegradable chassis 102 and/or the biodegradable cover 103 may have an ultimate tensile strength of at least 35 MPa, 40 MPa, 42 MPa, 44 MPa, 46 MPa, 48 MPa, or 50 MPa. The ultimate tensile strength can be measured in accordance with ISO527.

In certain embodiments, the cellulose acetate based material of the biodegradable chassis 102 and/or the biodegradable cover 103 depicted in the previous figures can have a flexural modulus of 1,500 MPa to 3,000 MPa. In certain embodiments, the cellulose acetate based material of the biodegradable chassis 102 and/or the biodegradable cover 103 may have a flexural modulus of 1,500 MPa to 2,000 MPa, 1,500 MPa to 2,250 MPa, 1,500 MPa to 2,520 MPa, 1,500 MPa to 2,750 MPa, 1,500 MPa to 3,000 MPa, 2,000 MPa to 2,250 MPa, 2,000 MPato 2,520 MPa, 2,000 MPa to 2,750 MPa, 2,000 MPa to 3,000 MPa, 2,250 MPa to 2,520 MPa, 2,250 MPa to 2,750 MPa, 2,250 MPa to 3,000 MPa, 2,520 MPa to 2,750 MPa, 2,520 MPa to 3,000 MPa, or 2,750 MPa to 3,000 MPa. In certain embodiments, the cellulose acetate based material of the biodegradable chassis 102 and/or the biodegradable cover 103 may have a flexural modulus of 1,500 MPa, 2,000 MPa, 2,250 MPa, 2,520 MPa, 2,750 MPa, or 3,000 MPa, or any value therein. In certain embodiments, the cellulose acetate based material of the biodegradable chassis 102 and/or the biodegradable cover 103 may have a flexural modulus of at least 1,500 MPa, 2,000 MPa, 2,250 MPa, 2,520 MPa, or 2,750 MPa. The flexural modulus can be measured in accordance with ISO178.

In certain embodiments, the cellulose acetate based material of the biodegradable chassis 102 and/or the biodegradable cover 103 depicted in the previous figures can have a flexural strength of 49 MPa to 65 MPa. In certain embodiments, the cellulose acetate based material of the biodegradable chassis 102 and/or the biodegradable cover 103 may have a flexural strength of 49 MPa to 53 MPa, 49 MPa to 55 MPa, 49 MPa to 57 MPa, 49 MPa to 59 MPa, 49 MPa to 61 MPa, 49 MPa to 65 MPa, 53 MPa to 55 MPa, 53 MPa to 57 MPa, 53 MPa to 59 MPa, 53 MPa to 61 MPa, 53 MPa to 65 MPa, 55 MPa to 57 MPa, 55 MPa to 59 MPa, 55 MPa to 61 MPa, 55 MPa to 65 MPa, 57 MPa to 59 MPa, 57 MPa to 61 MPa, 57 MPa to 65 MPa, 59 MPa to 61 MPa, 59 MPa to 65 MPa, or 61 MPa to 65 MPa. In certain embodiments, the cellulose acetate based material of the biodegradable chassis 102 and/or the biodegradable cover 103 may have a flexural strength of 49 MPa, 53 MPa, 55 MPa, 57 MPa, 59 MPa, 61 MPa, or 65 MPa, or any value therein. In certain embodiments, the cellulose acetate based material of the biodegradable chassis 102 and/or the biodegradable cover 103 may have a flexural strength of at least 49 MPa, 53 MPa, 55 MPa, 57 MPa, 59 MPa, or 61 MPa. The flexural strength can be measured in accordance with ISO178.

In certain embodiments, the cellulose acetate based material of the biodegradable chassis 102 and/or the biodegradable cover 103 depicted in the previous figures can have a heat deformation temperature of 63° C. to 75° C. In certain embodiments, the cellulose acetate based material of the biodegradable chassis 102 and/or the biodegradable cover 103 may have a heat deformation temperature of 63° C. to 65° C., 63° C. to 67° C., 63° C. to 68° C., 63° C. to 69° C., 63° C. to 70° C., 63° C. to 75° C., 65° C. to 67° C., 65° C. to 68° C., 65° C. to 69° C., 65° C. to 70° C., 65° C. to 75° C., 67° C. to 68° C., 67° C. to 69° C., 67° C. to 70° C., 67° C. to 75° C., 68° C. to 69° C., 68° C. to 70° C., 68° C. to 75° C., 69° C. to 70° C., 69° C. to 75° C., or 70° C. to 75° C. In certain embodiments, the cellulose acetate based material of the biodegradable chassis 102 and/or the biodegradable cover 103 may have a heat deformation temperature of 63° C., 65° C., 67° C., 68° C., 69° C., 70° C., or 75° C., or any value therein. In certain embodiments, the cellulose acetate based material of the biodegradable chassis 102 and/or the biodegradable cover 103 may have a heat deformation temperature of at least 63° C., 65° C., 67° C., 68° C., 69° C., or 70° C.

In certain embodiments, the cellulose acetate based material of the biodegradable chassis 102 and/or the biodegradable cover 103 depicted in the previous figures can have any one of, any combination of, or all of the properties mentioned herein, such as MFR, specific gravity, ultimate tensile strength, flexural modulus, flexural strength, and heat deformation temperature. The properties of the cellulose acetate based material of the biodegradable chassis 102 and the biodegradable cover 103 can be the same or different.

### B. Method of Producing the Electronic Device Assembly

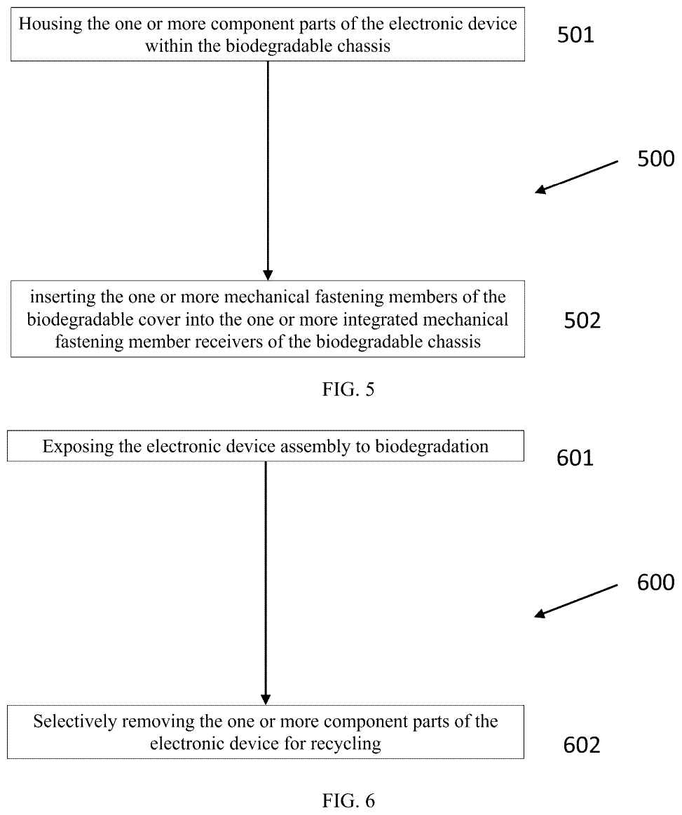

FIG. 5 depicts a flowchart of a method 500 for producing an electronic device assembly according to one example of the disclosure. In some aspects, the method 500 can include housing one or more component parts of an electronic device, such as the printed circuit board, antenna, antenna supports, pogo pin, and USB connector within a biodegradable chassis, at 501. In certain embodiments, a portion of the USB connector can extend out of the biodegradable chassis. The method 500 may also include inserting one or more mechanical fastening members of a biodegradable cover into the one or more integrated mechanical fastening member receivers of the biodegradable chassis, at 502. By inserting the one or more mechanical fastening members of the biodegradable cover into the one or more integrated mechanical fastening member receivers of the biodegradable chassis, the biodegradable cover can be inserted into the internal cavity of the biodegradable chassis and the one or more electronic component parts can be secured between the biodegradable cover and the biodegradable chassis.

C. Method of Separating One or More Component Parts of the Electronic Device from the Electronic Device Assembly for Recycling.

FIG. 6 depicts a flowchart of a method 600 for separating one or more component parts from an electronic device assembly for recycling according to some embodiments of the disclosure. The method 600 can include exposing an electronic device assembly to biodegradation, at 601. The method 600 can further include selectively removing the one or more component parts of the electronic device, such as the printed circuit board, antenna, antenna supports, pogo pin, and USB connector, for recycling, at 602. The one or more component parts of the electronic device can be removed before, during and/or subsequent to the biodegradation. In certain embodiments, the one or more component parts of the electronic device are removed subsequent to the biodegradation. Biodegradation of the electronic device assembly can include biodegradation of the biodegradable chassis, biodegradable cover, and/or the biodegradable printed circuit board. Biodegradation can be complete or partial biodegradation of the biodegradable chassis, biodegradable cover, and/or the biodegradable printed circuit board. In certain embodiments, the biodegradation can include exposing the biodegradable chassis and/or biodegradable cover to a biologically active environment, such as soil, sea water or fresh water, aerobic or anaerobic composting, activated sludge, sanitary landfill, or the like.

Although embodiments of the present invention and their advantages have been described in detail, it should be understood that various changes, substitutions and alterations can be made herein without departing from the spirit and scope of the embodiments as defined by the appended claims. Moreover, the scope of the present invention is not intended to be limited to the particular embodiments of the process, machine, manufacture, composition of matter, means, methods and steps described in the specification. As one of ordinary skill in the art will readily appreciate from the above disclosure, processes, machines, manufacture, compositions of matter, means, methods, or steps, presently existing or later to be developed that perform substantially the same function or achieve substantially the same result as the corresponding embodiments described herein can be utilized. Accordingly, the appended claims are intended to include within their scope such processes, machines, manufacture, compositions of matter, means, methods, or steps.

1. An electronic device assembly, comprising:
a biodegradable housing structure comprising:
a biodegradable chassis adapted to house one or more component parts of an electronic device, wherein the biodegradable chassis includes an internal cavity with one or more integrated mechanical fastening member receivers; and
a biodegradable cover insertable into the internal cavity of the biodegradable chassis, wherein the biodegradable cover includes one or more mechanical fastening members insertable into the one or more integrated mechanical fastening member receivers to secure the one or more component parts between the biodegradable cover and the biodegradable chassis.

2. The electronic device assembly of claim 1, wherein the one or more component parts include at least a printed circuit board and at least one antenna.

3. The electronic device assembly of claim 2, wherein the printed circuit board includes a biodegradable printed circuit board corresponding to a laminate formed from organic fibers impregnated with a water-soluble polymer and a halogen-free flame retardant.

4. The electronic device assembly of claim 2, wherein the at least one antenna includes at least one metal antenna, and wherein the one or more component parts further include one or more antenna supports disposed between the printed circuit board and the biodegradable cover.

5. The electronic device assembly of claim 4, wherein at least one of the one or more antenna supports is formed from natural rubber.

6. The electronic device assembly of claim 4, wherein the at least one metal antenna includes: a three-dimensional (3D) metal antenna for input/output radio waves; and an audio antenna disposed between the 3D metal antenna and at least one of the one or more antenna supports.

7. The electronic device assembly of claim 2, wherein the biodegradable cover is disposed adjacent to one surface of the printed circuit board, the electronic device assembly further comprising a Universal Serial Bus (USB) connector that is electronically coupled to the printed circuit board and that is disposed adjacent to an opposite surface of the printed circuit board.

8. The electronic device assembly of claim 7, wherein the USB connector includes a USB Type-C (USB-C) connector.

9. The electronic device assembly of claim 1, wherein the biodegradable chassis is formed from a cellulose acetate based material, a polyhydroxyalkanoate (PHA) material such as a poly (3-hydroxybutyrate) (PHB) material, or a combination thereof.

10. The electronic device assembly of claim 9, wherein the cellulose acetate material has one or more of the following material properties:
a melt flow rate (MFR) of 14 g/10 min, as measured in accordance with ISO1133;
a specific gravity of 1.3, as measured in accordance with ISO1183;
an ultimate tensile strength of 46 MPa, as measured in accordance with ISO527;
a flexural modulus of 2520 MPa, as measured in accordance with ISO178;
a flexural strength of 57 MPa, as measured in accordance with ISO178; and
a heat deformation temperature of 68° C., as measured in accordance with ISO75.

11. The electronic device assembly of claim 1, wherein the biodegradable cover is formed from a cellulose acetate based material, a polyhydroxyalkanoate (PHA) material such as a poly (3-hydroxybutyrate) (PHB) material, or a combination thereof.

12. The electronic device assembly of claim 11, wherein the cellulose acetate material has one or more of the following material properties:
a melt flow rate (MFR) of 14 g/10 min, as measured in accordance with ISO1133;
a specific gravity of 1.3, as measured in accordance with ISO1183;
an ultimate tensile strength of 46 MPa, as measured in accordance with ISO527;
a flexural modulus of 2520 MPa, as measured in accordance with ISO178;
a flexural strength of 57 MPa, as measured in accordance with ISO178; and
a heat deformation temperature of 68° C., as measured in accordance with ISO75.

13. A method for producing an electronic device assembly, the method comprising:
housing one or more component parts of an electronic device within a biodegradable chassis, wherein the biodegradable chassis includes an internal cavity with one or more integrated mechanical fastening member receivers; and
inserting a biodegradable cover into the internal cavity of the biodegradable chassis, wherein the biodegradable cover includes one or more mechanical fastening members insertable into the one or more integrated mechanical fastening member receivers to secure the one or more component parts between the biodegradable cover and the biodegradable chassis.

14. The method of claim 13, wherein the one or more component parts include at least:
a printed circuit board;
at least one metal antenna; and
one or more antenna supports disposed between the printed circuit board and the biodegradable cover, wherein at least one of the one or more antenna supports is formed from natural rubber.

15. The method of claim 14, wherein the at least one metal antenna includes: a three-dimensional (3D) metal antenna for input/output radio waves; and an audio antenna disposed between the 3D metal antenna and at least one of the one or more antenna supports.

16. The method of claim 14, wherein the biodegradable cover is disposed adjacent to one surface of the printed circuit board, the electronic device assembly further comprising a Universal Serial Bus (USB) connector that is electronically coupled to the printed circuit board and that is disposed adjacent to an opposite surface of the printed circuit board.

17. The method of claim 16, wherein the USB connector includes a USB Type-C (USB-C) connector.

18. The method of claim 13, wherein at least one of the biodegradable chassis and the biodegradable cover is formed from a cellulose acetate based material, a polyhydroxyalkanoate (PHA) material such as a poly (3-hydroxybutyrate) (PHB) material, or a combination thereof.

19. A method of separating one or more component parts from an electronic device assembly for recycling, the method comprising:
exposing an electronic device assembly to biodegradation, the electronic device assembly comprising:
a biodegradable chassis that houses component parts of an electronic device, the biodegradable chassis including an internal cavity with one or more integrated mechanical fastening member receivers; and
a biodegradable cover that includes one or more mechanical fastening members inserted into the one or more integrated mechanical fastening member receivers to secure the component parts between the biodegradable cover and the biodegradable chassis; and
subsequent to the biodegradation, selectively removing one or more of the component parts for recycling.

20. The method of claim 19, wherein the electronic device assembly is a small form factor wireless communication device having a Universal Serial Bus (USB) Type-C (USB-C) connector.
